(19) United States
(12) Patent Application Publication
(10) Pub. No.: US 2006/0203457 A1
(43) Pub. Date: Sep. 14, 2006

(54) Z-axis component connections for use in a printed wiring board

(75) Inventors: Galliano R. Busletta, Bloomsbury, NJ (US); Robert J. Roessler, Rockwall, TX (US); David L. Stevens, Sunnyvale, TX (US)

Correspondence Address: HITT GAINES P.C., P.O. BOX 832570, RICHARDSON, TX, 75083, US

(73) Assignee: Tyco Electronics Power Systems, Inc.

(21) Appl. No.: 11/079,841

(22) Filed: Mar. 14, 2005

(51) Int. Cl. H05K 1/18

(52) U.S. Cl. 361/761; 29/832; 174/260

(57) ABSTRACT

The present invention provides, in one aspect, a printed wiring board (PWB) for attaching electrical components thereto, comprising, multiple PWB insulating layers located between conductive layers, an interconnect edge that intersects the conductive layers, and an electrical device, wherein at least a portion of the electrical device is located along the interconnect edge and electrically connects at least a portion of the conductive layers to each other.

### TECHNICAL FIELD OF THE INVENTION

The present invention is directed, in general, to printed wiring boards (PWB) and, more specifically, to a PWB having a Z-axis component within a connection opening located in the PWB.

### BACKGROUND

In general, the demand for smaller, yet more powerful, electronic circuit modules, which have more features or capabilities and greater component density than their predecessors, has been steadily increasing. This is especially true in the case of PWBs configured as power converters that are often employed in power supplies. A power converter is a power processing circuit that converts an input voltage waveform into a specified output voltage waveform. In many applications requiring a DC output, switched-mode DC/DC power converters are frequently employed to an advantage wherein both high conversion density and converter efficiency are key design requirements.

In current PWBs, the electrical components or devices are surface mounted onto the board. Solder is typically used to electrically connect and mount the electrical devices to the board's surface. As component density has increased, the space availability for these additional components has become ever increasingly more problematic.

In addition to the components, a significant amount of board space is also needed for the vias required to make the connections necessary for the increased number of electrical components. In conventional vias, the conductive material covers the entire interior wall of or in some cases fills the via. In such structures, any conductive trace that the via intersects is electrically connected to every other conductive trace that also intersects that same via. This results in only one electrical connection for each via.

When the board layout is complex and includes many electrical components, the number of vias (and the concomitant amount of board space consumed by both) increases dramatically. Therefore, it becomes very difficult for manufacturers to keep the board dimensions and layout within specified design requirements and yet still provide the required number of electrical devices and connections necessary for the proper operation of the device.

As mentioned above, electrical devices are typically surface mounted and placed on the outermost layer of the PWB. While dimensions of these components have shrunk significantly over time, the increased power and performance requirements have caused device density on the surface of the PWB to substantially increase, and thereby consume additional space on the PWB. Together, the surface mounted components and the increased number of vias consume an undesirable amount of board space.

To overcome the component density problems, manufacturers have turned to embedding passive devices, such as capacitors and resistors in XY planes located between insulating layers of the PWB itself. While this does reduce the number of surface mounted components, this manufacturing method requires a number of processing steps that are both time consuming and costly. Thus, a more cost effective way of reducing component density on the PWB is still needed.

Accordingly, what is needed is a PWB with an interconnect and component system that over come the disadvantages associated with via of the prior art PWBs.

### SUMMARY OF INVENTION

To address the above-discussed deficiencies of the prior art, the present invention provides, in one embodiment a printed wiring board (PWB) for attaching electrical components thereto, comprising, multiple PWB insulating layers located between conductive layers, an interconnect edge that intersects the conductive layers, and an electrical device, wherein at least a portion of the electrical device is located along the interconnect edge and electrically connects at least a portion of the conductive layers to each other.

In another embodiment, the present invention includes a method of manufacturing a printed wiring board (PWB) for attaching electrical components thereto. In one embodiment, the method comprises assembling multiple PWB insulating layers located between conductive layers, forming an interconnect edge that intersects the conductive layers, and placing at least a portion of an electrical device along the interconnect edge such that the electrical device electrically connects at least a portion of the conductive layers to each other.

In yet another embodiment, the present invention provides an electrical circuit that comprises a printed wiring board (PWB), comprising multiple PWB insulating layers located between conductive layers, an interconnect edge that intersects the conductive layers, and an electrical device. The PWB further includes surface mounted electrical devices attached to an outermost surface of the PWB and electrically connected to form an operative electrical circuit.

The foregoing has outlined preferred and alternative features of the present invention so that those of ordinary skill in the art may better understand the detailed description of the invention that follows. Additional features of the invention will be described hereinafter that form the subject of the claims of the invention. Those skilled in the art should appreciate that they can readily use the disclosed conception and specific embodiment as a basis for designing or modifying other structures for carrying out the same purposes of the present invention. Those skilled in the art should also realize that such equivalent constructions do not depart from the scope of the invention.

### BRIEF DESCRIPTION OF THE DRAWINGS

The invention is best understood from the following detailed description when read with the accompanying FIGUREs. It is emphasized that in accordance with the standard practice in the semiconductor industry, various features may not be drawn to scale. In fact, the dimensions of the various features may be arbitrarily increased or reduced for clarity of discussion. Reference is now made to the following descriptions taken in conjunction with the accompanying drawings, in which:

FIG. 1 illustrates a simplified, exploded view of an embodiment of an electric circuit formed on a multi-leveled PWB that can be constructed according to the principles of the present invention;

FIG. 2 illustrates an enlarged, partial sectional view of a PWB as covered by one embodiment of the present invention;

FIG. 3 illustrates a partial sectional view of an alternative embodiment of a PWB as provided by the present invention;

FIG. 4 illustrates an enlarged, partial sectional view of the PWB of FIG. 3 at an early stage of via fabrication;

FIG. 5 illustrates an enlarged, partial sectional view of the PWB of FIG. 4 subsequent to the formation of ledges;

FIG. 6 illustrates a partial, sectional view of the PWB of FIG. 5 after the formation and partial removal of a conductive layer;

FIG. 7 illustrates a partial, sectional view of an alternative embodiment of an opening having multiple ledges therein in which an electrical device can be located;

FIG. 8 illustrates a partial, section view of an edge of the PWB that has a conductive edge and an electrical device located thereon and an electrical device located within a via positioned interior of the perimeter edge of the PWB;

FIG. 9A illustrates a partial, sectional view of a PWB, which is the same as the embodiment shown in FIG. 3, except that an electrical device contacts only a portion of conductive layers;

FIG. 9B illustrates a partial, sectional view of another embodiment of the PWB of FIG. 9A wherein electrical devices are located within both sides of the opening that extend through the PWB;

FIG. 9C illustrates a partial, sectional view of the PWB of FIG. 9B illustrating how the Z-axis of the PWB can be used to place an electrical device within an opening extending through the PWB, thereby providing additional surface space for more surface mounted components and the achievement of greater component density on the PWB; and

FIG. 10 illustrates an overhead view of a power converter in which the present invention may be implemented.

### DETAILED DESCRIPTION

The present invention recognizes that the Z-axis of a PWB can be used to reduce component density on a PWB by utilizing openings, such as vias, or external edges of a PWB. The electrical device can be placed at least partially, if not entirely, into the opening or can be adhered to an edge of the PWB, both of which utilize the Z-axis of the PWB, and thereby reduce the number of surface mounted components on the PWB. This can be done without adding a significant number of processing steps, as required by conventional processes.

Moreover, an interconnect edge located within the opening or along an external edge of the PWB, in combination with the electrical device, can be used to make interconnections between various layers of the PWB. This unique utilization provides advantages over the prior art in that it allows for more diverse electrical interconnections throughout the board, while providing additional space on the board. The increase in available surface board space arises from the fact that the Z-axis of the PWB is utilized in that the electrical device, or at least a portion of it, can be located within an opening, or on an external edge of the PWB in place of being mounted on the surface of the board. The utilization of the PWB's Z-axis makes additional space available for more surface mounted components and allows the manufacturer to achieve increased component densification. These alternative Z-axis placement locations afford a meaningful increase in the amount of space that is available for other surface mounted components, thus meeting industry's strict size and ever increasing component density requirements for on-board technologies.

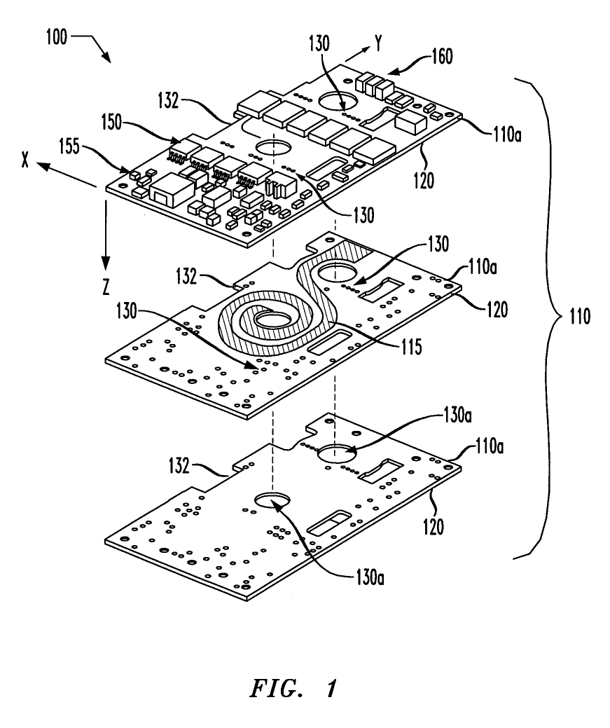

Referring initially to FIG. 1, illustrated is a simplified, exploded view of an embodiment of an electric circuit 100 formed on a multi-leveled PWB 110 that can be constructed according to the principles of the present invention. It should be noted that the electrical circuit 100 is illustrative only and that the present invention is applicable in any PWB that can be used for any type of electrical circuit application.

In the exemplary embodiment shown in FIG. 1, the PWB 110 includes multiple insulating layers 110a and conductive layers 115, which in many embodiments will be trace patterns of conductive material, as noted below. For clarity of description of the various embodiments discussed herein, the respective directions of the X, Y, and Z axis of the PWB 110 is also shown. In an advantageous embodiment, these insulating layers 110a are constructed with conventional materials. The number and configuration of these layers in the PWB 110 depend on the design and overall requirements or application of the device in which it is to be used. The conductive layer 115 may also be conventional. For example, the conductive layer 115 may be a patterned copper layer trace formed on one or more of the insulating layers 110a. Even though the present figure illustrates just one conductive layer 115, it should be understood that, typically, a conductive layer 115 will be located between each pair of insulating layers 110a, and each conductive layer 115 will be patterned to design specifications, and as such, can have different pathway and interconnect configurations. However, designs may vary, and a conductive layer may not necessarily be between every pair of insulating layers 110a, or it may even be a trace on the top and bottom of the PWB 110 itself.

The insulating layers 110a have an edge 120 at the exterior perimeter of the PWB 110 and openings 130 that are formed in or through the PWB 110. As explained in more detail below, an electrical device, which is not shown in this particular view can be placed within the openings 130 or on the edge 120 to utilize the Z-axis of the PWB 110, and by doing so, provide more outer surface area on which to mount additional surface mounted components.

In one embodiment, the opening 130 may be a via, or the opening 130 may be some type of other opening 130a extending through the PWB 110. However, in other embodiments, the opening 130 may simply be an intentional cut-out edge 132 for providing an edge plating surface. The edge 120, or interior edges of openings 130 and 130a, and cut-out edge 132, can be plated with a conductive material to form an interconnect edge, as discussed below to serve as an interconnect for the electrical device, as mentioned above.

Further illustrated in this exploded view are other conventional surface mounted electrical components, such as FETs 150, resistors 155, and capacitors 160, all of which may be employed in an electrical circuit, such as a power converter. With a general overview of the electrical circuit 100 having been described, a more detailed discussion of an embodiment of the PWB 110 will now be discussed.

It should be understood that the fabrication processes and materials used to generally make the PWB 110, as described herein, may be conventional. Thus, those skilled in the art, when made aware of the present invention, will be able to construct the PWB 110 and electrical circuit 100.

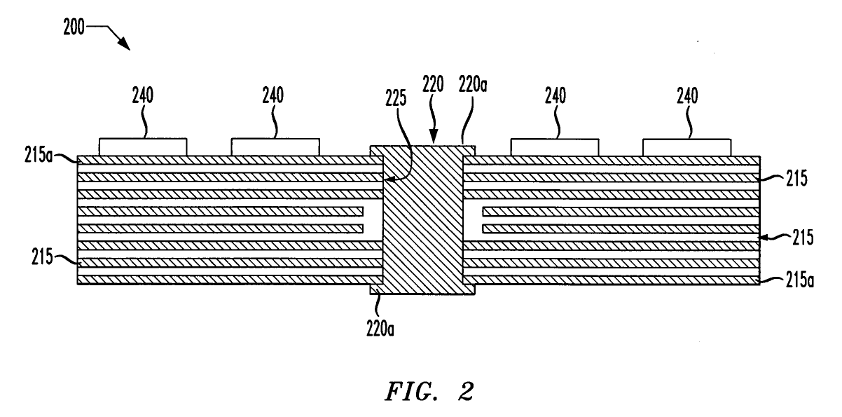

Turning now to FIG. 2, there is illustrated an enlarged, partial sectional view of a PWB 200 as covered by one embodiment of the present invention. The PWB 200 includes multiple insulating layers 210 as those discussed above and are of conventional construction and design. Conductive layers 215, such as patterned traces, only two of which are designated for simplicity, are located between the insulating layers 210. The conductive layers 215 are also of conventional construction and design. The conductive layers 215 may be of any configuration or design as required by the application in which they are to be used. For example, the conductive layers 215 may be a trace pattern, as shown in FIG. 1 or may have some other design layout.

Also shown is an electrical device 220 located along the Z-axis and within an opening 225, such as a via, formed in or through the PWB 200. In this embodiment, the Z-axis direction of the opening 225 intersects at least a portion of the conductive layers 215, and as such, the electrical device 220 can provide electrical connection between the various conductive layers 215 However, in other embodiments, the opening 225 may intersect only the outermost conductive layers 215a. The electrical device 220 is a device whose function is to modify an electrical signal to cause the electric circuit to operate according to a predetermined specification and whose purpose is just not conduction. Examples of such devices, include, among others, a capacitor or resistor. This is in contrast to conventional vias that are plated or filled with a conductive material, such as solder, and whose primary or sole purpose is only to conduct the electrical signal to other portions of the circuit.

Additionally, conventional configurations include electrical devices that are electrically connected to other devices only by an electrical lead that extends from the body of the electrical device and into the opening 225. The present invention is different from these conventional configurations in that the body of the electrical device 220, or at least a portion thereof, is located within the opening 225 or along an outer edge of the PWB 200 versus having just a lead that extends into the opening 225. It should be noted however that this does not preclude a lead of the electrical device 220 from being located within the opening 225 or on an external edge of the PWB 200 along with the electrical device 220, itself. Moreover, it should further be understood that while the illustrated embodiments show the electrical device 220 extending throughout the entire length of the opening 225, the electrical device 220 need not do so. As such, it need not contact all of the conductive layers 215, 215a that intersect the opening 225.

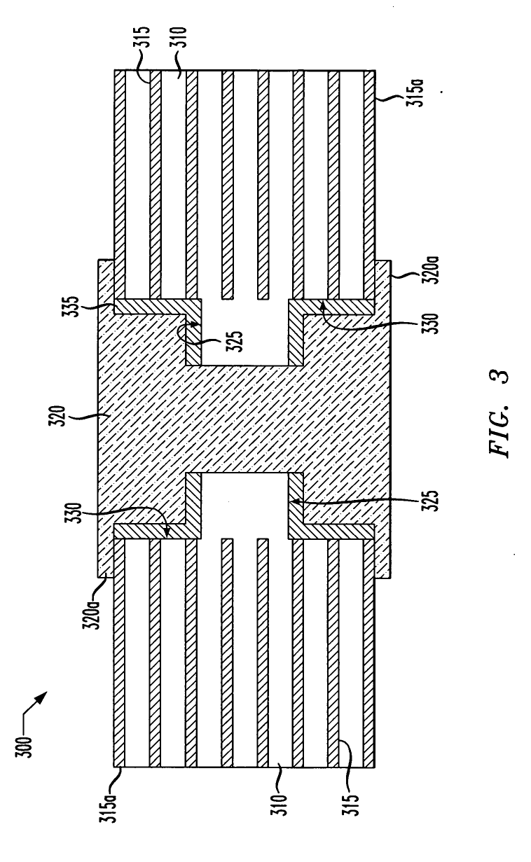

As mentioned above, the opening 225 may be a conventional via, or it may have a unique configuration as described below regarding FIG. 3. In the illustrated embodiment of FIG. 2, the opening 225 extends through the entire thickness of the PWB 200 and intersects the conductive layers 215. However, other embodiments can include openings that do not extend entirely through the PWB 200 and are within the scope of the present invention as well. The inner walls of the opening 225 itself can serve as an interconnect edge for the conductive layers 215, 215a, and the electrical device 220. In such instances, the electrical device 220 provides electrical connection among the conductive layers 215, 215a that the opening 225 intersects.

The opening 225 may be located anywhere on the board and may be of any geometric design of depth. For example, the opening 225 may be a via interior to the perimeter of the PWB 200, or it may be an edge or cut-out edge located at the outer perimeter of the PWB 200, as noted above with respect to FIG. 1. The electrical device 220 electrically connects internal conductive layers 215 that intersect the opening 225 with each other. In addition, however, in the illustrated embodiment, the electrical device 220 make addition electrical connection with the outermost conductive layer 215a by way of the overlapping edges 220a. Various electrical components 240, such as those mentioned above, can be located on the outermost surface of the PWB 200 and schematically shown and electrically connected to form an operative integrated circuit. As those who are skilled in the art can easily see, the combination and the number of ways that the electrical device 220 can be electrically associated with the conductive layers 215 and 215a will depend on which conductive layers 215, 215a, the opening intersects. For example, if the opening 225 intersects only the outer layers 215a, then the electrical device 220 will be electrically associated only with the outer layers 215a located on opposite sides of the PWB 200. Alternatively, if the opening 225 intersects internal conductive layers 215, then those layers will be electrically associated with the electrical device 220.

As seen from FIG. 2, the unique Z-axis placement of the electrical device 220 in the opening 225 or along an edge of the PWB 200 provides more space on the surface of the PWB 200. For example, in conventional applications, a capacitor or resistor are placed on the surface of the PWB 200, but in the present invention, these components can be located either entirely or partially within the opening 225 or along an edge of the PWB 200, and thereby and allow for the achievement of even greater component density.

Turning now to FIG. 3, there is illustrated a partial sectional view of an alternative embodiment of a PWB 300 as provided by the present invention. In this embodiment, the PWB 300 also includes multiple insulating layers 310 that have conductive layers 315 therebetween, again only a couple of which have been designated for simplicity, and outermost conductive layers 315a. In this embodiment, the electrical device 320 is located within an opening 330 that has ledges 325 within its interior. The formation of opening 330 is briefly discussed below in some detail and provides great flexibility in making multiple and separate electrical connections to other portions of the PWB 300 from a single opening 330. Thus, in one embodiment, the PWB 300 will include these uniquely configured openings 330 wherein some of a number of the openings 330 include the electrical device 320 and some do not. Together, however, they allow for greater utilization of the surface of the PWB 300, since more connections can be made with a single opening 330, thereby reducing the number of required openings 330 and more components can be surface mounted on the PWB 300 because the electrical devices 320 can be located within some of the openings 330.

As with the previous embodiment, the opening 330 can serve as the interconnect edge for the conductive layers 315 and 315a with the electrical device 320 providing electrical connection among the conductive layers 315 and 315a. However, an exemplary embodiment may also include a conductive layer 335 deposited using the same processes used to plate conventional vias in PWBs, such as the one previously described regarding FIG. 2. Thus, one skilled in the art will understand how to achieve such a deposition.

In the illustrated embodiment, a portion of the conductive layer 335 has been removed, and accordingly contacts only a portion of the conductive layers 315 that abut the opening 330. As such, when the electrical device 320 is positioned within the opening 330, it provides electrical connection among the conductive layers 315 and 315a. It should be noted that while the illustrated embodiment shows the electrical device 320 extending the entire length of the opening 330, other embodiments include those configuration where the electrical device 320 does not extend the entire length of the opening 330. Thus, in certain embodiments, the electrical device 320 may contact only a portion of the conductive layers 315, 315a.

Because of the unique aspect of the opening 330 and its application with the electrical device 320, a brief discussion of the formation of the opening 330 is set forth below.

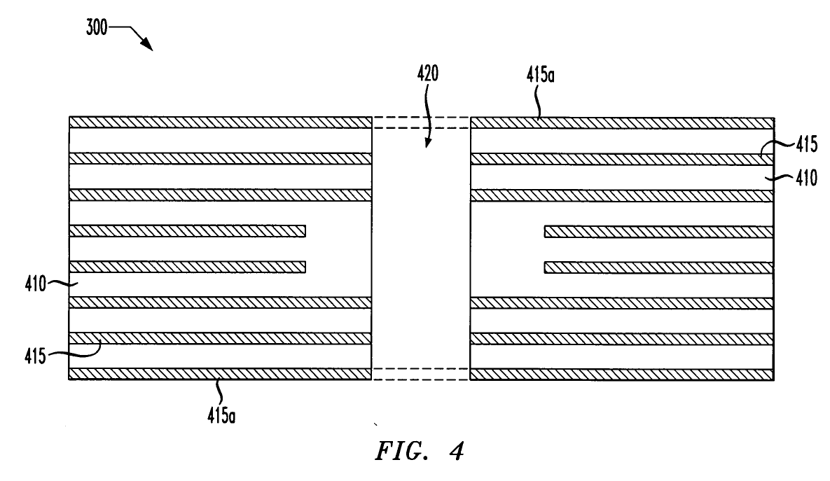

Referring now to FIG. 4, there is shown an enlarged, partial sectional view of the PWB 300 of FIG. 3 at an early stage of via fabrication. Like the PWB 200 of FIG. 2, PWB 300 includes multiple insulating layers 410 that have conductive layers 415 therebetween, again only a couple of which have been designated for simplicity, and outermost conductive layers 415a. In this embodiment, there is shown an opening 420 formed through PWB 300, which in this embodiment, is a pilot opening. The opening 420, in one embodiment, is formed by drilling a hole through PWB 300, which can be accomplished with a conventional drill tool, laser, or other cutting mechanism capable of creating the opening 420, such as a router. The opening 420 is not limited to any one geometric shape or dimension. For example, the opening 420 may be circular, or it may have a rectangular shape. Further, as mentioned above, the location of the opening 420 on PWB 300 may be any where there is a need for an interconnect structure, including an edge of PWB 300. One who is skilled in the art will recognize that the size of the cutting tool can be adjusted to achieve the desired dimensional configuration shown in this embodiment.

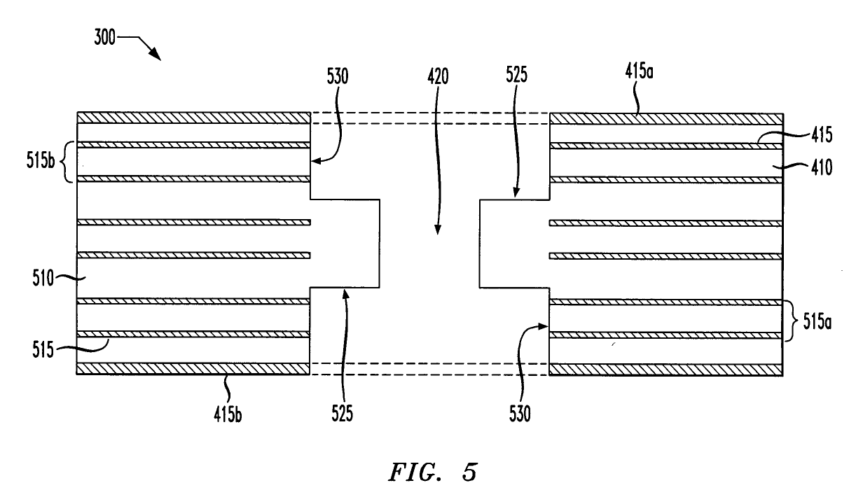

Turning now to FIG. 5, there is shown an enlarged, partial sectional view of the PWB 300 of FIG. 4 subsequent to the formation of ledges 525. The ledges 525 may be formed in a number of ways. In one embodiment, the ledges 525 are formed using a drill bit that has a larger diameter than the drill bit used to form the opening 420. The drill bit is used to drill to a depth sufficient to intersect the desired number of conductive layers 415 and form interconnect openings 530. Those who are skilled in the art, given the teachings herein, would understand how to stagger the drill sizes to achieve the desired interconnect structure. For example, the drill bit sizes may range from about 0.022 inches to about 0.40 inches. Alternatively, in the case where a laser or router is used, the cutting diameter would be appropriately adjusted. As seen in FIG. 5, the interconnect openings 530 have larger circumferences than the original opening 420 and are formed in such a way to form openings that are substantially concentric with the opening 420. Also seen from FIG. 5 is the aspect that the interconnect openings 530 can be formed on opposite sides of the PWB 300. In such embodiments, the opening 420 is common to the opposing interconnect openings 530. Alternatively, one interconnect opening 530 may be formed in only one side of the PWB 300. As mentioned above, the ledges 525 of the interconnect opening 420, respectively, can be configured to separate a first group of conductive layers 515a from a second group of conductive traces 515b.

In one embodiment, the interconnect openings 530 may be formed using another cutting tool, such as a router, whose blade can be adjusted to different depths to form the ledges 525. In another aspect, the interconnect openings 530 may be formed first, after which, opening 420 may be formed using a drill or other cutting tool that will result in the opening 420 having a circumference that is smaller than the interconnect openings 530.

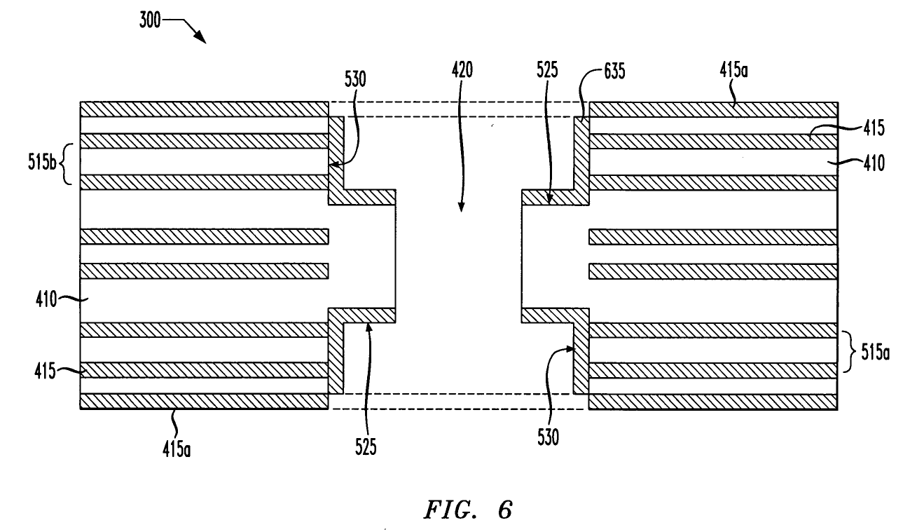

Turning now to FIG. 6, there is illustrated a partial, sectional view of the embodiment illustrated in FIG. 5 after conventional deposition of a conductive layer 635 and partial removal thereof. The conductive layer 635 may be deposited using the same processes used to plate conventional vias in PWBs. Thus, one skilled in the art will understand how to achieve such a deposition. As seen at this point of the fabrication process, the conductive layer 635 contacts only a portion of the conductive layers 415. This is achieved by removing a portion of the conductive layer 635 by adjusting the cutting tool to the appropriate diameter such that it removes the portion of the opening 420 that is common to the interconnect openings 530 to electrically disconnect the first group of conductive layers 515a from the second group of conductive layers 515b. In another embodiment, however, a portion of the conductive layer 635 may not be removed. In such embodiments, the conductive layer 635 would extend the entire depth of length of the openings 530 and 420. In doing so, the conductive layer 635 would electrically connect the conductive layers 415 that abut the opening 530.

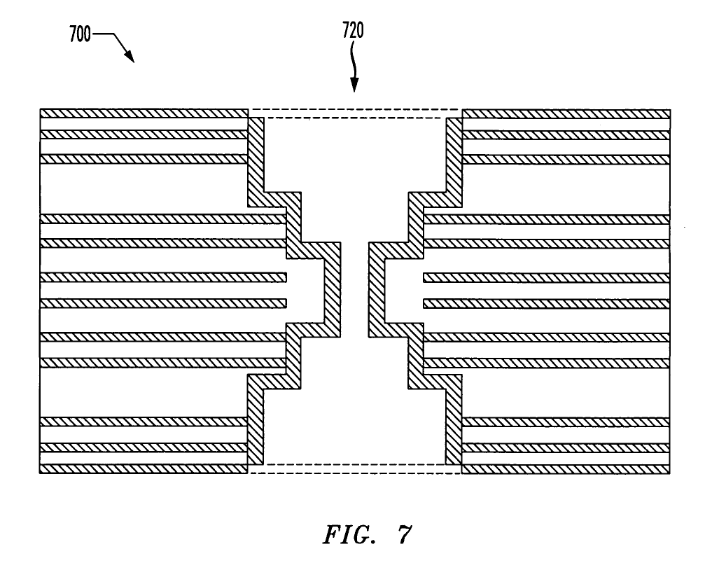

If desired additional edges can be formed in the opening 530 by using the appropriate number of sequential cutting bits having with the appropriate diameter size, or alternatively, if a laser or some other cutting tool is used, the cutting beam, etc. of the cutting device can be adjusted to form a mutli-ledged opening 720, as illustrated in FIG. 7.

Following formation of the opening 530 or the partial removal of the conductive layer 635 in those embodiments where it is removed, and the formation of the appropriate number of ledges, the electrical device 320 of FIG. 3 is located in the openings 530 and 420 to arrive at the exemplary structure illustrated in FIG. 3. The manner in which the electrical device is positioned within the opening 530 is explained below in more detail.

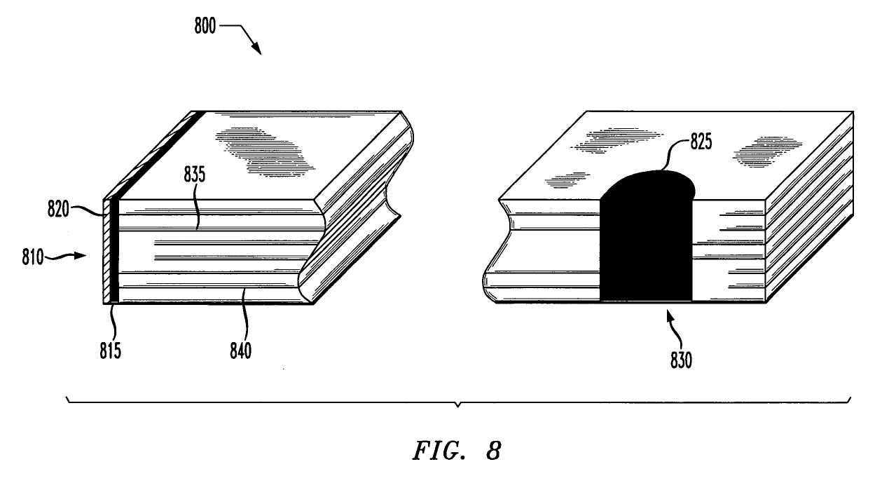

Referring now briefly to FIG. 8, there is illustrated a partial section view of an edge 810 of the PWB 800 that has a conductive edge 815 and an electrical device 820 located thereon and an electrical device 825 located within a via 830 positioned interior of the perimeter edge of the PWB 800, as explained above. FIG. 8, briefly illustrates how electrical conductive edge 815 and electrical device 820 interconnects conductive layers 835 and 840. As seen from FIG. 8, because the electrical device 820 can positioned along the Z-axis (along the edge 810 of the via 830) of the PWB 800, the XY plane that would otherwise be occupied by the electrical device 820 is available for additional components.

As briefly mentioned above, the electrical device may be a number of electrical devices conventionally found on PWBs, such as those used to form power converters. In an advantageous embodiment, the electrical device is a passive device, such as a capacitor or resistor. In one embodiment, the electrical device is formed from a curable paste, slurry or thick polymer film. These materials are well known and commercially available from a number of sources, such as DuPont, Sanmina, 3M and Oaki Mitsui, and Asahi Chemical/Motorola, DuPont, Shipley or Gould, respectively. For example, the capacitor paste may be an expoy/barium titinate (BaTiO₃) or a polyamide BaTiO₃ that is curable at about 150 degrees centigrade. The resistor paste may be a phenolic based material that is also curable at about 150 degrees centigrade.

During manufacture, the appropriate paste or slurry is applied to the appropriate openings or onto the desired edges. The application may be accomplished by way of screen printing, plugging or putting the appropriate openings or edges. In an advantageous embodiment, the paste or slurry completely fills the opening as shown above, or at least partially fills the opening, and the excess paste or slurry is removed and cured with heat.

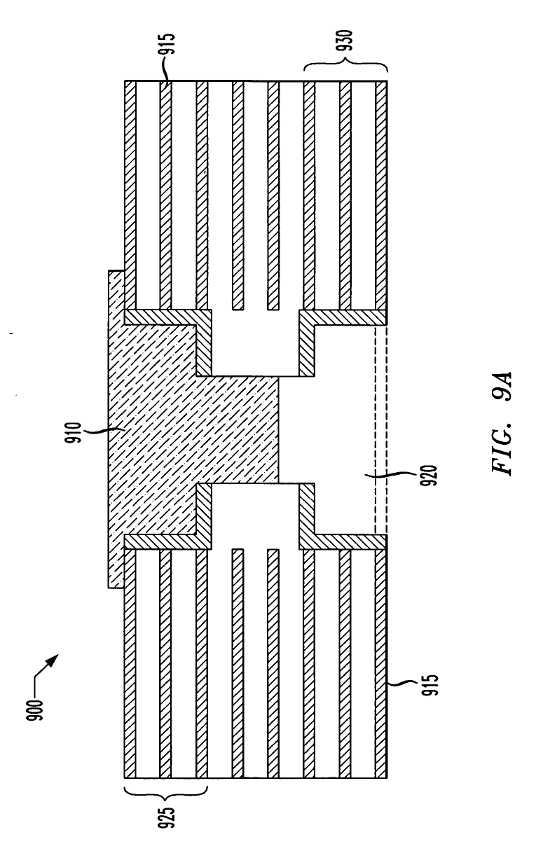

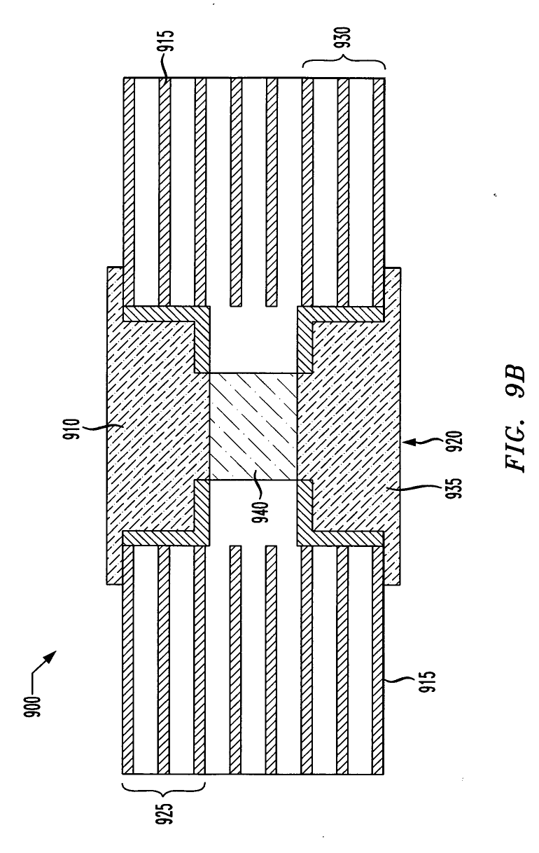

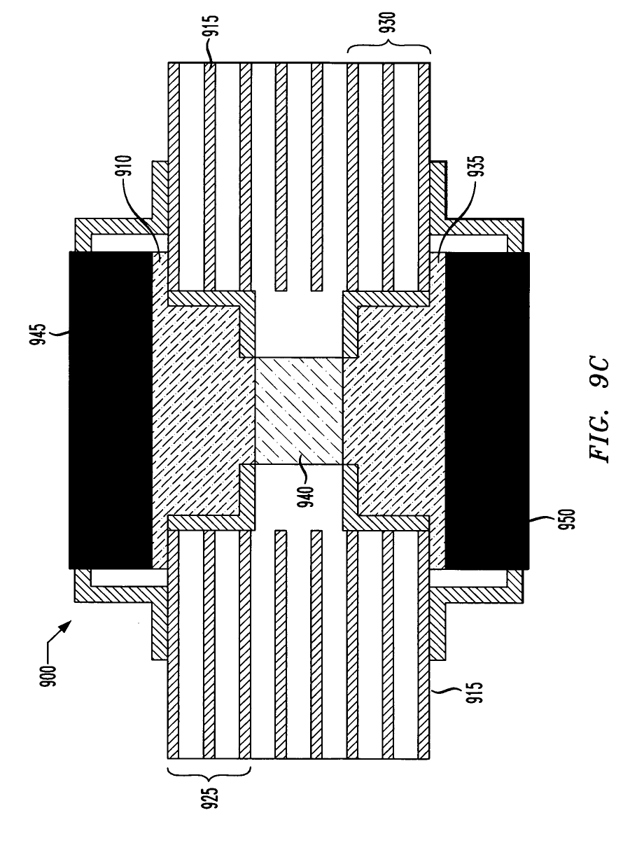

FIG. 9A illustrates a partial, sectional view of a PWB 900, which is the same as the embodiment shown in FIG. 3, except that an electrical device 910 contacts only a portion of conductive layers 915. As seen in this embodiment, the paste or slurry does not completely fill the opening 920. In these instances, a portion of the opening 920 may be plugged prior to the screening process to assure that the paste or slurry contacts only the desired level of conductive layers or traces. As shown here, the electrical device 910 contacts only a first group of conductive layers 925 and does not contact a second group of conductive layers 930. As such, the first group of conductive layers 925 is electrically isolated from the second group of conductive layers 930. Alternatively, in other embodiments, a portion of the cured electrical device 910 may be physically removed to achieve this same level of conductivity between the conductive layers or traces.

FIG. 9B is a partial, sectional view of another embodiment of the PWB 900 where a second electrical device 935 is located in an opposite side of the opening 920. As seen, the electrical devices 910 and 935 are separated by an insulative region 940, such as a dielectric material. In this particular embodiment, the illustrated structure can be formed by plugging the middle portion of the opening 920 and then placing the electrical device 910 or 935 in the respective outer portion of the opening 920, in a manner as described above with respect to other embodiments. The plug can then be removed and an insulative material can then be located within the middle portion of the opening 920 to form the insulative region 940. If excess insulative material remains, it is removed and an electrical device can then be positioned in the remaining outer portion of the opening 920. As seen in the illustrative embodiment, the electrical device 910 is electrically associated with conductive layers 925, while the electrical device 920 is electrically associated with conductive layers 930. However, other electrical configurations are also within the scope of the present invention. The electrical devices 910 and 935 may be the same type of device, or they may be different. For example, they both may be capacitors or resistors, or one may be a capacitor and the other may be a resistor. The insulative region 940 provides electrical isolation between the electrical devices 910 and 920 and conductive layers 925 and 930.

Referring now to FIG. 9C, there is shown a partial, sectional view of the PWB 900 of FIG. 9B illustrating how the electrical devices 910 and 935 can be used in conjunction with other electrical components 945 and 950, respectively. This clearly illustrates the advantage of how the Z-axis of a PWB 900 can be used to place an electrical device or devices, 910 and 935 within an opening. This Z-axis placement allows the other electrical components 945 and 950 to be placed over the electrical device 910 and 935. As such, mounting space typically occupied by the electrical devices 910 and 935 can be used to mount additional components to the surface of the PWB 900. Thus, greater component density on the PWB 900 can be achieved. It should be noted that this electrical configuration is exemplary only and those skilled in the art should understand that, given the teachings herein, various electrical configurations can be achieved using the principles of the present invention.

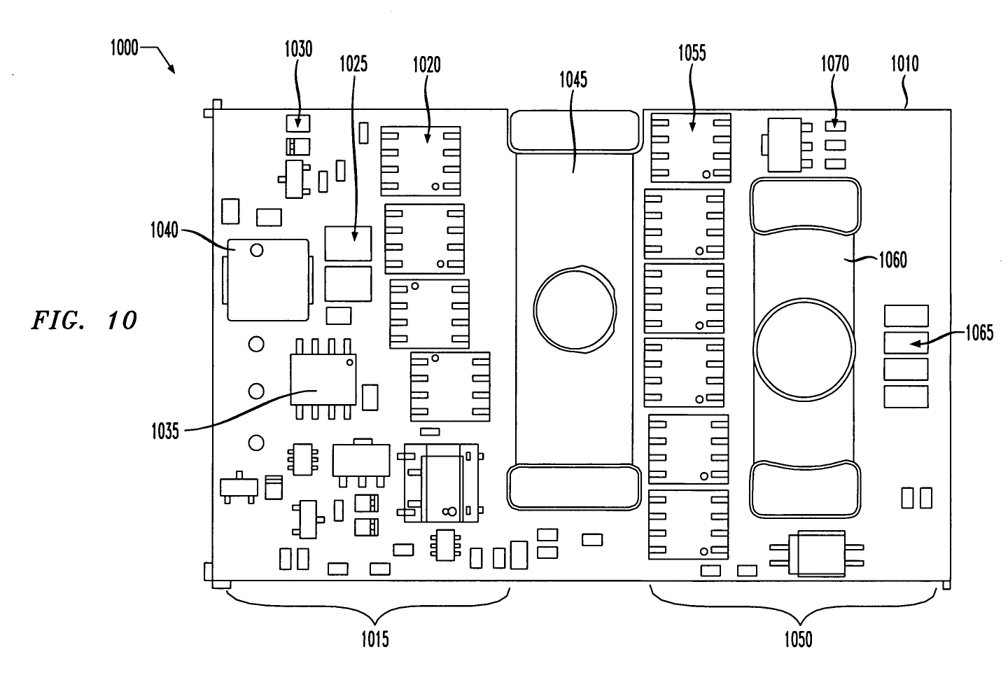

Turning now to FIG. 10, there is illustrated an overhead view of a power converter 1000 implementing the edge plate interconnects provided by the present invention and as discussed above with respect to other embodiments. In this embodiment, the power converter 1000 includes a PWB 1010 including the insulating layers and conductive layers, as discussed above. In one embodiment, the power converter 1000 includes a primary circuit 1015, including primary inverter switches 1020, primary capacitors 1025, primary resistors 1030, a primary controller 1035 and a primary inductor 1040. In one embodiment, the primary circuit 1015 is electrically connected to the primary winding of a transformer 1045, as described above. The power converter 1000 further includes a secondary circuit 1050 that includes rectifier switches 1055, an output inductor 1060, output capacitors 665 and output resistors 1070. The secondary circuit 1050 is electrically connected to the secondary winding of the transformer 1045, as also described above. As mentioned above, once in possession of the present invention, one who is skilled in the art would know how to construct the power convert 1000.

Although the present invention has been described in detail, one who is of ordinary skill in the art should understand that they can make various changes, substitutions, and alterations herein without departing from the scope of the invention.

What is claimed is:

1. A printed wiring board (PWB) for attaching electrical components thereto, comprising:
multiple PWB insulating layers located between conductive layers;
an interconnect edge that intersects the conductive layers; and
an electrical device wherein at least a portion of the electrical device is located along the interconnect edge and electrically connects at least a portion of the conductive layers to each other.

2. The PWB as recited in claim 1, wherein the interconnect edge is located within an opening formed through the PWB or is an external edge located at an outer perimeter of the PWB.

3. The PWB as recited in claim 2, wherein the opening further has ledges therein.

4. The PWB as recited in claim 1, wherein the electrical device interconnects internal conductive layers located between outermost layers of the PWB.

5. The PWB as recited in claim 1, wherein the electrical device extend through the PWB and interconnects conductive layers located on opposing outermost surfaces of the PWB.

6. The PWB as recited in claim 1, wherein the interconnect edge is a conductive liner that contacts the conductive layers that terminate at the interconnect edge and the electrical device contacts the conductive liner along at least a portion of the interconnect edge.

7. The PWB as recited in claim 6, wherein the conductive liner is segmented and a first segment contacts a first group of the conductive layers and a second segment contacts a second group of the conductive layers, and wherein the first group and second group of the conductive layers are electrically connected by the electrical device.

8. The PWB as recited in claim 1, wherein the electrical device is a capacitor, a resistor, an inductor, or a diode.

9. A method of manufacturing a printed wiring board (PWB) for attaching electrical components thereto, comprising:
assembling multiple PWB insulating layers located between conductive layers;
forming an interconnect edge that intersects the conductive layers; and
placing at least a portion of an electrical device along the interconnect edge such that the electrical device electrically connects at least a portion of the conductive layers to each other.

10. The method as recited in claim 9, wherein forming the interconnect edge comprises locating the interconnect edge within an opening formed through the PWB or on an external edge located at an outer perimeter of the PWB.

11. The method as recited in claim 9, further comprising forming the opening such that the opening has ledges therein.

12. The method as recited in claim 9, wherein placing the electrical device comprises placing the electrical device such that the electrical device interconnects internal conductive layers located between outermost insulating layers of the PWB.

13. The method as recited in claim 9, wherein placing the electrical device comprises the electrical device such that the electrical device extends through the PWB and interconnects conductive layers located on opposing outermost surfaces of the PWB.

14. The method as recited in claim 9, wherein forming the interconnect edge comprises forming a conductive liner that contacts the conductive layers that terminate at the interconnect edge and placing comprises placing the electrical device to contact the conductive liner along at least a portion of the conductive liner.

15. The method as recited in claim 14, wherein forming the conductive liner comprises forming a segmented conductive line wherein a first segment contacts a first group of the conductive layers and a second segment contacts a second group of the conductive layers, and wherein the first group and second group of the conductive layers are electrically connected by the electrical device.

16. The method as recited in claim 9, placing the electrical device comprises placing a paste, slurry or polymer along the interconnect edge and reflowing the paste, slurry or polymer.

17. The method as recited in claim 16 wherein the electrical device is a capacitor, a resistor, an inductor, or a diode.

18. An electrical circuit, comprising:
a printed wiring board (PWB), comprising:
multiple PWB insulating layers located between conductive layers;
an interconnect edge that intersects the conductive layers; and
an electrical device wherein at least a portion of the electrical device is located along the interconnect edge and electrically connects at least a portion of the conductive layers to each other; and
surface mounted electrical devices attached to an outermost surface of the PWB and electrically connected to form an operative electrical circuit.

19. The electrical circuit as recited in claim 18, wherein the electrical circuit is a power converter.

20. The electrical circuit as recited in claim 18, wherein the interconnect edge is located within an opening formed through the PWB or is an external edge located at an outer perimeter of the PWB, the opening further having ledges therein and the electrical device interconnects internal conductive layers located between outermost layers of the PWB or interconnects conductive layers located on opposing outermost surfaces of the PWB.
